(19) United States
(12) Patent Application Publication
(10) Pub. No.: US 2014/0247559 A1
(43) Pub. Date: Sep. 4, 2014

(54) HEAT DISSIPATION STRUCTURE OF ELECTRONIC SHIELD COVER

(71) Applicant: CHE-YUAN WU, NEW TAIPEI CITY (TW)

(72) Inventor: CHE-YUAN WU, NEW TAIPEI CITY (TW)

(21) Appl. No.: 13/903,262

(22) Filed: May 28, 2013

(30) Foreign Application Priority Data
Mar. 4, 2013 (TW) 102203948

(51) Int. Cl. H05K 9/00

(52) U.S. Cl. CPC H05K 9/0007
USPC 361/704

(57) ABSTRACT

A heat dissipation structure of electronic shield cover, which is applicable to a heat-conductive and magnetically conductive isolation case that encloses a preset heat source for dissipating heat. The heat dissipation structure includes: an electroconductive heat conduction plate assembly having at least one contact face in contact with a surface of the isolation case; and a heat spreader, which is able to transversely conduct heat. The heat spreader has an area smaller than that of the heat conduction plate assembly and is disposed on the heat conduction plate assembly in contact therewith. The heat spreader has a proximal-to-heat-source section proximal to the heat source and a distal-from-heat-source section extending in a direction away from the heat source. The heat conduction plate assembly and the heat spreader cooperate with each other to quickly dissipate the heat and avoid accumulation of the heat around the heat source.

### BACKGROUND OF THE INVENTION

1. Field of the Invention

The present invention relates generally to a heat dissipation structure of electronic shield cover, and more particularly to a heat dissipation structure, which is applicable to an isolation case for quickly and uniformly dissipating the heat generated by a heat source so as to avoid accumulation of the heat around the heat source and avoid abnormal rise of the temperature of a local section of the isolation case.

2. Description of the Related Art

It is known that an electrically conductive and magnetically conductive shield cover (generally made of metal material) is often used to enclose and cover electronic components on a circuit board so as to prevent the electronic components from being interfered with by external electromagnetic waves. Along with popularization and diversification of the application of the electronic components, the electronic components enclosed in the shield cover have become unlimited to low-power heat generation components and more and more high-power electronic components (such as processors and power transistors) are also arranged in the shield cover. The high-power electronic components will generate high heat in operation. The shield cover defines a closed space isolated from outer side so that the heat dissipation efficiency for the electronic components is poor. As a result, it often takes place that the heat generated by the electronic components accumulates around the heat source to cause excessive rise of the temperature of a local section of the shield cover. This will serious affect the operation of the electronic components.

In order to solve the above problem of excessive rise of the temperature of the local section, in general, a heat conduction component with better heat conduction efficiency, (such as a heat pipe), is used to partially contact the shield cover. In addition, a heat dissipation assembly (such as radiating fin assembly or cooling fan) is disposed on another part of the heat conduction component. The heat conduction component serves to transfer the heat to the other part to be dissipated from the heat dissipation assembly. In this case, the heat is prevented from concentrating so that the excessive rise of the temperature of the local section can be avoided.

However, the cost for the above structure is relatively high and it is uneconomic to apply such structure to the low-price electronic products. Moreover, in the above structure, most of the heat is dissipated by way of radiation so that the heat dissipation effect is not satisfying.

### SUMMARY OF THE INVENTION

It is therefore a primary object of the present invention to provide a heat dissipation structure of electronic shield cover, which is able to quickly spread and outward dissipate the heat generated by a heat source in a direction away from the heat source so as to avoid concentration of the heat and abnormal rise of the temperature of a local area.

It is a further object of the present invention to provide the above heat dissipation structure of electronic shield cover, in which no expensive heat conduction component is used so that the manufacturing cost of the heat dissipation structure is lowered to promote the economic efficiency.

To achieve the above and other objects, the heat dissipation structure of electronic shield cover of the present invention includes: a heat-conductive and magnetically conductive isolation case disposed around at least one preset heat source to enclose the heat source; at least one heat conduction plate assembly having at least one electroconductive heat conduction plate; and at least one heat spreader, which is able to quickly conduct heat along the surface. The heat spreader is attached to and in contact with the heat conduction plate assembly. The heat spreader has a proximal-to-heat-source section proximal to the heat source and a distal-from-heat-source section distal from the heat source. At least one of the heat conduction plate assembly and the heat spreader is in contact with the isolation case.

In the above heat dissipation structure of electronic shield cover, the heat conduction plate assembly includes at least two heat conduction plates. The heat spreader is disposed between the heat conduction plates in contact with the heat conduction plates.

In the above heat dissipation structure of electronic shield cover, the heat conduction plates of the heat conduction plate assembly have equal size and identical shape.

In the above heat dissipation structure of electronic shield cover, the heat spreader has an area smaller than that of the heat conduction plates.

In the above heat dissipation structure of electronic shield cover, the heat spreader is an elongated plate body.

In the above heat dissipation structure of electronic shield cover, the heat spreader has an elongated main extension section and at least one branch section obliquely extending from one side of the main extension section.

In the above heat dissipation structure of electronic shield cover, the heat spreader has an elongated main extension section and at least one branch section obliquely extending from each of two sides of the main extension section.

In the above heat dissipation structure of electronic shield cover, the branch section obliquely extends in a direction away from the heat source assembly and the main extension section.

In the above heat dissipation structure of electronic shield cover, an electroconductive adhesive layer is disposed between the heat conduction plate assembly and the heat spreader.

In the above heat dissipation structure of electronic shield cover, an electroconductive adhesive layer is disposed between the isolation case and the heat conduction plate assembly.

In the above heat dissipation structure of electronic shield cover, the isolation case is composed of an isolation casing surrounding the heat source and an isolation cover mated with upper side of the isolation casing to cover the heat source.

The present invention can be best understood through the following description and accompanying drawings, wherein:

### BRIEF DESCRIPTION OF THE DRAWINGS

FIG. 1 is a perspective exploded view of a first embodiment of the present invention;

FIG. 2 is a perspective partially assembled view of the first embodiment of the present invention, showing that the first embodiment of the present invention is applied to an isolation case;

FIG. 3 is a perspective assembled view of the first embodiment of the present invention, showing the application thereof;

FIG. 4 is a perspective assembled view of a second embodiment of the present invention, showing the application thereof;

FIG. 5 is a perspective assembled view of a third embodiment of the present invention, showing the application thereof;

FIG. 6 is a perspective exploded view of a fourth embodiment of the present invention;

FIG. 7 is a perspective assembled view of the fourth embodiment of the present invention, showing the application thereof;

FIG. 8 is a perspective assembled view of a fifth embodiment of the present invention, showing the application thereof; and

FIG. 9 is a perspective assembled view of a sixth embodiment of the present invention, showing the application thereof.

### DETAILED DESCRIPTION OF THE PREFERRED EMBODIMENTS

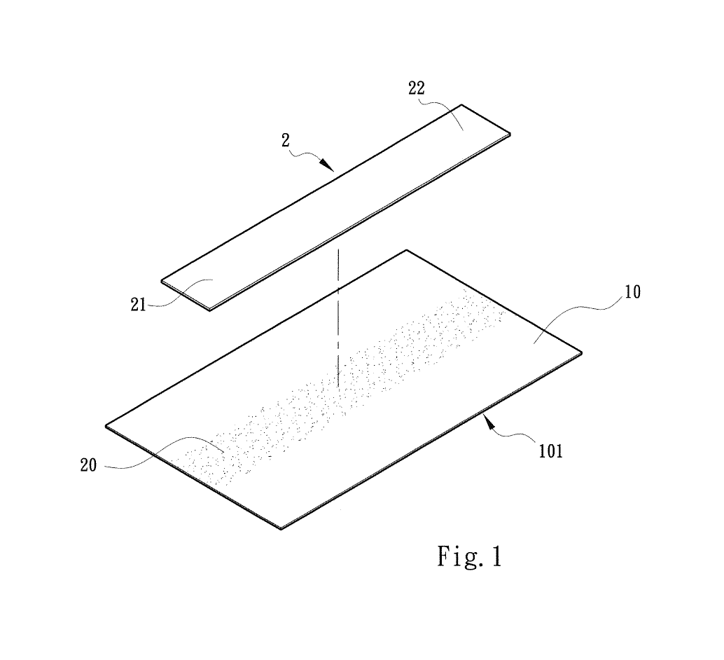

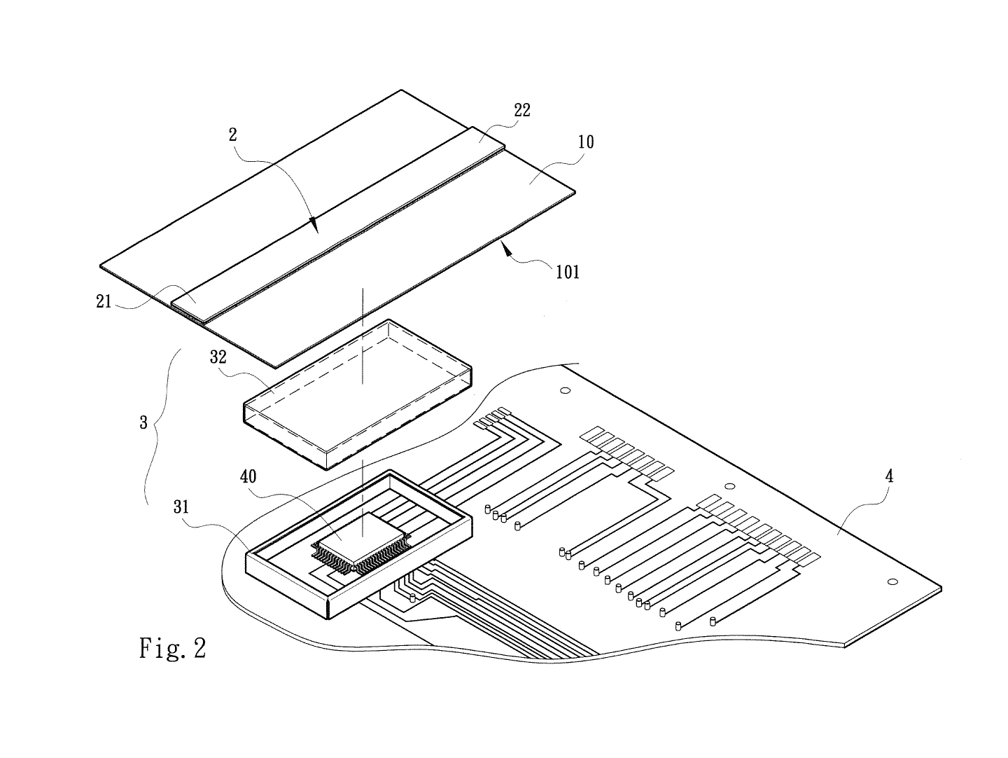

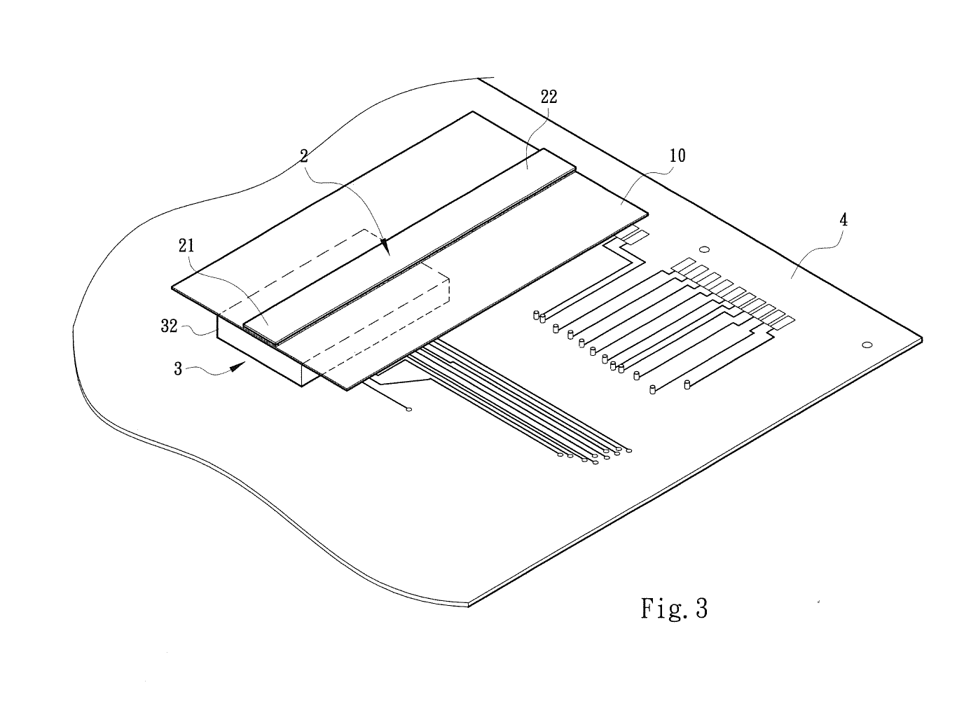

Please refer to FIGS. 1 to 3. According to a first embodiment, the heat dissipation structure of electronic shield cover of the present invention includes a heat conduction plate assembly 10 and a heat spreader 2. The heat conduction plate assembly 10 is one single heat conduction plate (made of metal material) with electroconductivity. One face of the heat conduction plate (heat conduction plate assembly 10) is provided with a contact face 101. In practice, the heat conduction plate (heat conduction plate assembly 10) is applicable to an isolation case 3 enclosing a heat source 40. In this embodiment, the heat source 40 is an electronic component arranged on a circuit board 4, (such as a processor, a power transistor, etc.) The isolation case 3 is composed of an isolation casing 31 surrounding the heat source 40 and an isolation cover 32 mated with upper side of the isolation casing 31 to cover the heat source 40. The contact face 101 of the heat conduction plate (heat conduction plate assembly 10) is in contact with the isolation case 3. An electroconductive adhesive layer is disposed between the isolation case 3 (isolation cover 32) and the contact face 101 of the heat conduction plate (heat conduction plate assembly 10), whereby the relevant components are more securely electrically connected with each other (for grounding or other purposes).

The heat spreader 2 is a plate-shaped structure body with an area smaller than that of the heat conduction plate assembly 10 (heat conduction plate). The heat spreader 2 can be made of graphite or the like material. In this embodiment, the heat spreader 2 is an elongated plate body, which has a property of quickly conducting heat along the surface (transversely). The heat spreader 2 is attached to and in contact with the heat conduction plate assembly 10 (heat conduction plate). In practice, the heat spreader 2 can be an electrical conductor. An electroconductive adhesive layer 20 can be disposed between the heat spreader 2 and the heat conduction plate assembly 10 (heat conduction plate) as necessary, whereby the heat spreader 2 and the heat conduction plate assembly 10 (heat conduction plate) are electrically connected with each other. The heat spreader 2 has a proximal-to-heat-source section 21 proximal to the heat source 40 and a distal-from-heat-source section 22 extending in a direction away from the heat source 40.

In use, most of the heat generated by the heat source 40 is conducted from the isolation case 3 through the contact face 101 to the heat conduction plate assembly 10 (heat conduction plate). The heat conduction plate assembly 10 (heat conduction plate) is made of metal material and is able to uniformly radially spread the heat at equal speed. Therefore, the heat can quickly pass through the heat conduction plate assembly 10 (heat conduction plate) and be transferred to the heat spreader 2. Then, due to the property of quickly conducting heat along the surface (transversely) of the heat spreader 2, the heat is quickly spread from the proximal-to-heat-source section 21 proximal to the heat source 40 to the distal-from-heat-source section 22 distal from the heat source 40. Then the heat is outward dissipated from the heat conduction plate assembly 10 (heat conduction plate) without accumulating around the isolation case 3. In this case, the temperature of the isolation case 3 will not locally abnormally rise. Also, the heat conduction plate assembly 10 (heat conduction plate) and the heat spreader 2 are electrically connected with each other and grounded via the isolation case 3.

In the above heat dissipation structure of the present invention, the heat spreader 2 is disposed on one face of the heat conduction plate assembly 10 (heat conduction plate), which face is distal from the isolation case 3 (heat source 40). However, in practice, alternatively, the heat spreader 2 can be disposed on one face of the heat conduction plate assembly 10 (heat conduction plate), which face is proximal to the heat source 40 or even in direct contact with the isolation case 3 (heat source 40). This can achieve the same heat dissipation effect.

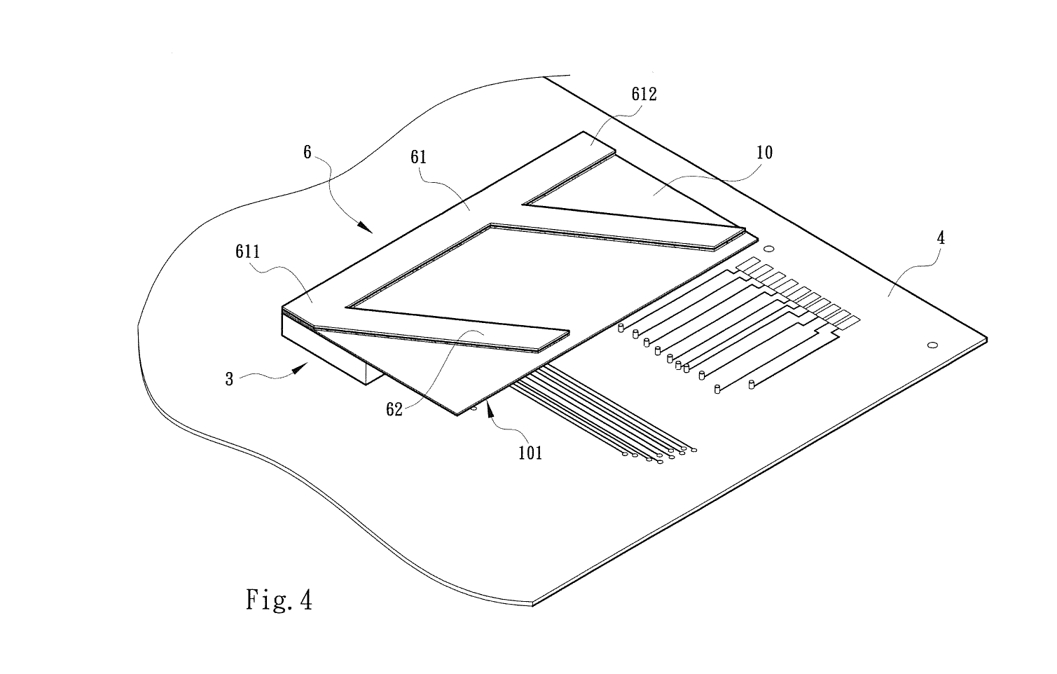

Please now refer to FIG. 4, which shows a second embodiment of the present invention. The second embodiment includes a heat spreader 6 and a heat conduction plate assembly 10 identical to that of the first embodiment. The heat conduction plate assembly 10 is in contact with and assembled on the isolation case 3 (isolation cover 32) in the same manner as the first embodiment. The heat spreader 6 is a plate-shaped structure body disposed on one side of the heat conduction plate assembly 10 (heat conduction plate). An electroconductive adhesive layer can be disposed between the heat conduction plate assembly 10 (heat conduction plate) and the heat spreader 6 as necessary. The heat spreader 6 has an elongated main extension section 61 and multiple branch sections 62 obliquely extending from one side of the main extension section 61 in parallel to each other. The branch sect ions 62 obliquely extend in a direction away from the heat source 40 and the main extension section 61. The main extension section 61 has a proximal-to-heat-source section 611 proximal to the heat source 40 and a distal-from-heat-source section 612 extending in a direction away from the heat source 40.

In use, most of the heat generated by the heat source 40 is conducted from the isolation case 3 through the contact face 101 to the heat conduction plate assembly 10 (heat conduction plate). The heat spreader 6 then quickly spreads the heat to those sections that are distal from the heat source 40 (to the distal-from-heat-source section 612 of the main extension section 61 and to the free ends of the branch sections 62). Then the heat is outward dissipated from the heat conduction plate assembly 10 (heat conduction plate) without accumulating around the isolation case 3. Also, the heat conduction plate assembly 10 and the heat spreader 6 can be electrically connected to a grounding section of the circuit board 4 via the isolation case 3.

In practice, as necessary, the heat spreader 6 can be disposed on one face of the heat conduction plate assembly 10 (heat conduction plate), which face is distal from the heat source 40 or disposed on one face of the heat conduction plate assembly 10 (heat conduction plate), which face is proximal to the heat source 40. Both can achieve the same heat dissipation effect.

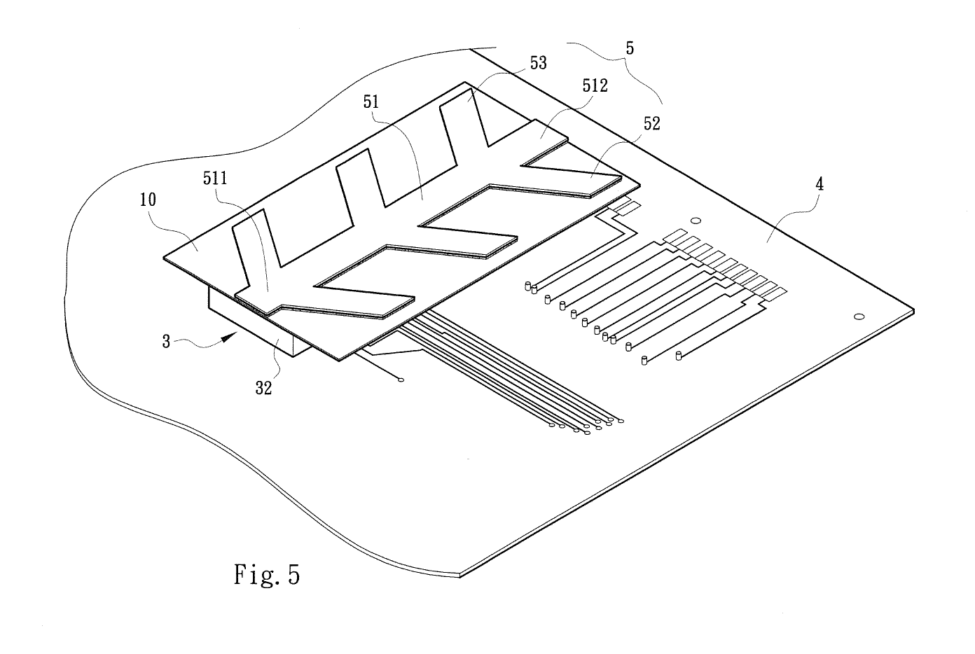

Please now refer to FIG. 5, which shows a third embodiment of the present invention. The third embodiment includes a heat spreader 5 and a heat conduction plate assembly 10 identical to that of the first embodiment. The heat conduction plate assembly 10 is in contact with and assembled on the isolation case 3 (isolation cover 32) in the same manner as the first embodiment. The heat spreader 5 is a plate-shaped structure body disposed on one side of the heat conduction plate assembly 10 (heat conduction plate). An electroconductive adhesive layer can be disposed between the heat conduction plate assembly 10 (heat conduction plate) and the heat spreader 6 as necessary. The heat spreader 5 has an elongated main extension section 51 and multiple branch sections 52, 53 obliquely extending from two sides of the main extension section 51 in parallel to each other. The branch sections 52, 53 obliquely extend in a direction away from the heat source 40 and the main extension section 51. The main extension section 51 has a proximal-to-heat-source section 511 proximal to the heat source 40 and a distal-from-heat-source section 512 extending in a direction away from the heat source 40.

In use, most of the heat generated by the heat source 40 is conducted from the isolation case 3 through the contact face 101 to the heat conduction plate assembly 10 (heat conduction plate). The heat spreader 5 then quickly spreads the heat to those sections that are distal from the heat source 40 (to the distal-from-heat-source section 512 of the main extension section 51 and to the free ends of the branch sections 52, 53). Then the heat is conducted back to the heat conduction plate assembly 10 (heat conduction plate) and outward dissipated from the heat conduction plate assembly 10 (heat conduction plate) without accumulating around the isolation case 3.

In practice, as necessary, the heat spreader 5 can be disposed on one face of the heat conduction plate assembly 10 (heat conduction plate), which face is distal from the heat source 40 or disposed on one face of the heat conduction plate assembly 10 (heat conduction plate), which face is proximal to the heat source 40. Both can achieve the same heat dissipation effect.

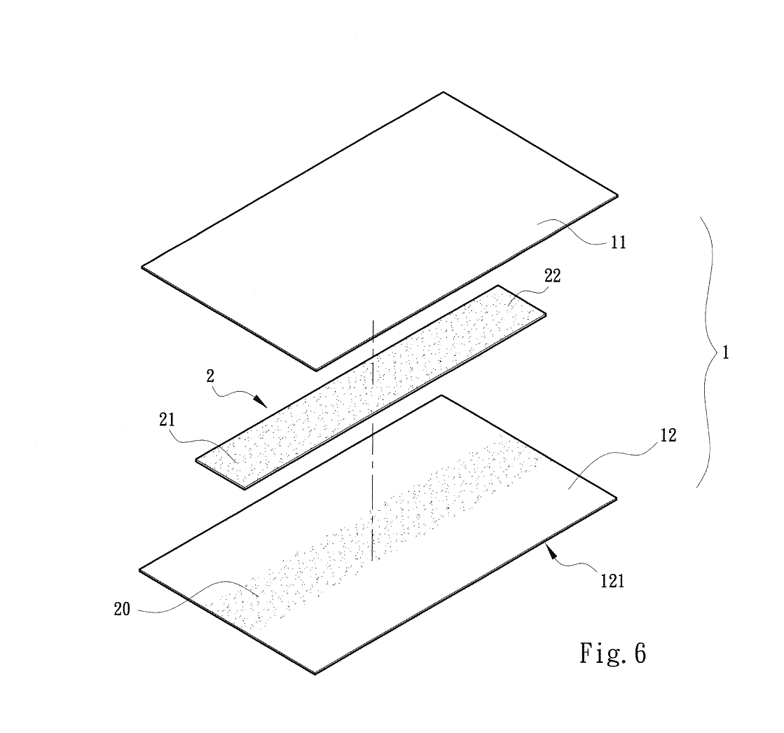

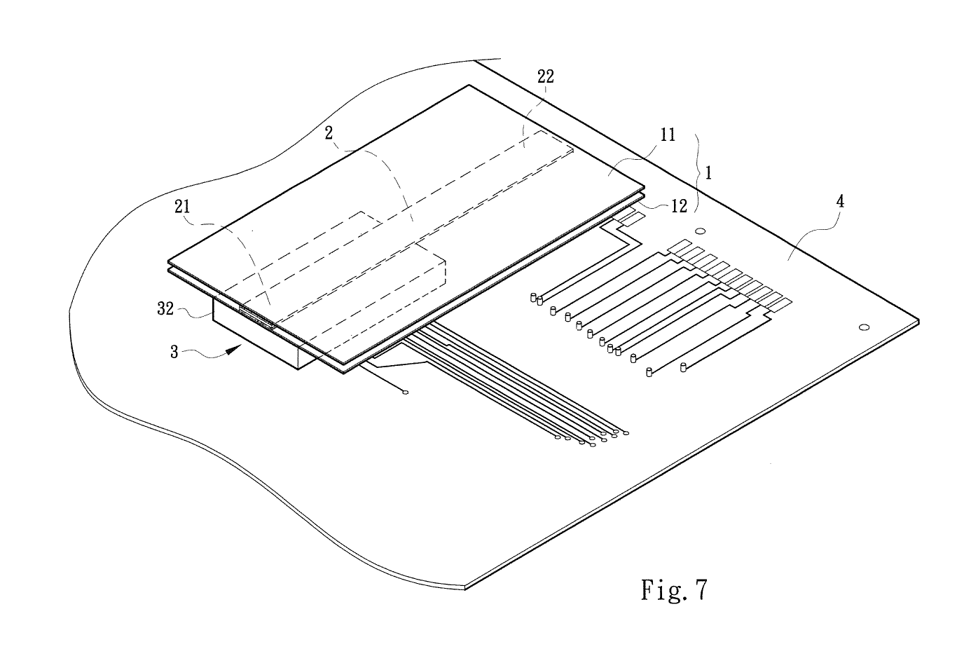

Please now refer to FIGS. 6 and 7, which show a fourth embodiment of the present invention. The fourth embodiment includes a heat conduction plate assembly 1 and a heat spreader 2 identical to that of the first embodiment. The heat conduction plate assembly 1 includes two heat conduction plates 11, 12 (made of metal material) with electroconductivity. A contact face 121 is formed on a face of the heat conduction plate 12, which face is distal from the heat conduction plate 11. (Alternatively, the contact face can be formed on a face of the heat conduction plate 11, which face is distal from the heat conduction plate 12). In practice, the heat conduction plate assembly 1 is applicable to an isolation case 3 enclosing a heat source 40 as in the first embodiment. In this embodiment, the contact face 121 of the heat conduction plate assembly 1 is in contact with the isolation case 3 (the isolation cover 32). An electroconductive adhesive layer is disposed between the isolation case 3 (isolation cover 32) and the contact face 121 of the heat conduction plate assembly 1, whereby the relevant components are more securely electrically connected with each other (for grounding or other purposes).

The heat spreader 2 is a plate-shaped structure body with an area smaller than that of the heat conduction plate assembly 1 (heat conduction plates 11, 12). The heat spreader 2 can be made of graphite or the like material. The heat spreader 2 is disposed between the heat conduction plates 11, 12 and attached to and in contact with the heat conduction plates 11, 12. In this embodiment, the heat spreader 2 is an elongated plate body, which has a property of quickly conducting heat along the surface (transversely). The heat spreader 2 can be an electrical conductor. Electroconductive adhesive layers 20 can be disposed between the heat spreader 2 and the heat conduction plates 11, 12 as necessary, whereby the heat spreader 2 and the heat conduction plates 11, 12 are electrically connected with each other. The heat spreader 2 has a proximal-to-heat-source section 21 proximal to the heat source 40 and a distal-from-heat-source section 22 extending in a direction away from the heat source 40.

In use, most of the heat generated by the heat source 40 is conducted from the isolation case 3 through the contact face 121 to the heat conduction plate 12 of the heat conduction plate assembly 1. The heat conduction plate 12 is made of metal material and is able to uniformly radially spread the heat at equal speed. Therefore, the heat can quickly pass through the heat conduction plate 12 and be transferred to the heat spreader 2. Then, due to the property of quickly conducting heat along the surface (transversely) of the heat spreader 2, the heat is quickly spread from the proximal-to-heat-source section 21 proximal to the heat source 40 to the distal-from-heat-source section 22 distal from the heat source 40. Then the heat is conducted from the heat spreader 2 to the heat conduction plates 11, 12 and outward dissipated from the heat conduction plates 11, 12 without accumulating around the isolation case 3. In this case, the temperature of the isolation case 3 will not locally abnormally rise. Also, the heat conduction plates 11, 12 and the heat spreader 2 are electrically connected with each other and grounded via the isolation case 3.

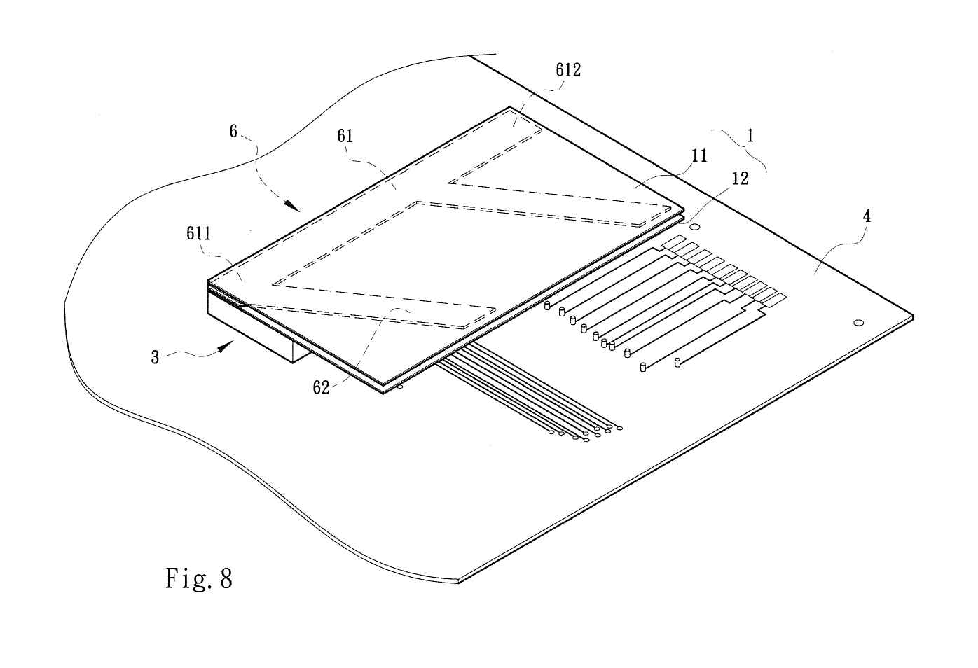

Please now refer to FIG. 8, which show a fifth embodiment of the present invention. The fifth embodiment includes a heat conduction plate assembly 1 and a heat spreader 6 identical to that of the second embodiment. The heat conduction plate assembly 1 includes two heat conduction plates 11, 12 (made of metal material) with electroconductivity. A contact face 121 is formed on a face of the heat conduction plate 12, which face is distal from the heat conduction plate 11. (Alternatively, the contact face can be formed on a face of the heat conduction plate 11, which face is distal from the heat conduction plate 12). In practice, the heat conduction plate assembly 1 is applicable to an isolation case 3 enclosing a heat source 40 as in the first embodiment. In this embodiment, the contact face 121 of the heat conduction plate assembly 1 is in contact with the isolation case 3 (the isolation cover 32). An electroconductive adhesive layer is disposed between the isolation case 3 (isolation cover 32) and the contact face 121 of the heat conduction plate assembly 1, whereby the relevant components are more securely electrically connected with each other (for grounding or other purposes).

The heat spreader 6 is a plate-shaped structure body disposed between the heat conduction plates 11, 12. (Electroconductive adhesive layers can be disposed between the heat spreader 6 and the heat conduction plates 11, 12 as necessary). The heat spreader 6 has an elongated main extension section 61 and multiple branch sections 62 obliquely extending from one side of the main extension section 61 in parallel to each other. The branch sections 62 obliquely extend in a direction away from the heat source 40 and the main extension section 61. The main extension section 61 has a proximal-to-heat-source section 611 proximal to the heat source and a distal-from-heat-source section 612 extending in a direction away from the heat source 40.

In use, most of the heat generated by the heat source 40 is conducted from the isolation case 3 through the contact face 121 to the heat conduction plate 12. The heat spreader 6 then quickly spreads the heat to those sections that are distal from the heat source 40 (to the distal-from-heat-source section 612 of the main extension section 61 and to the free ends of the branch sections 62). Then the heat is conducted back to the heat conduction plates 11, 12 and outward dissipated from the heat conduction plates 11, 12 without accumulating around the isolation case 3.

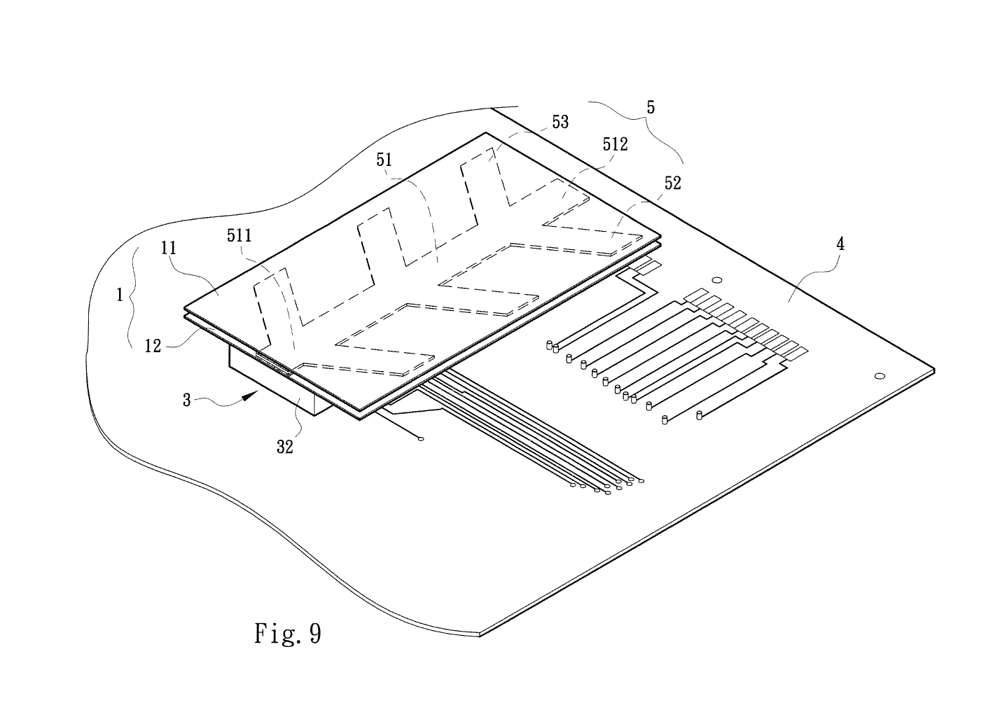

Please now refer to FIG. 9, which show a sixth embodiment of the present invention. The sixth embodiment includes a heat conduction plate assembly 1 and a heat spreader 5 identical to that of the third embodiment. The heat conduction plate assembly 1 includes two heat conduction plates 11, 12 (made of metal material) with electroconductivity. A contact face 121 is formed on a face of the heat conduction plate 12, which face is distal from the heat conduction plate 11. (Alternatively, the contact face can be formed on a face of the heat conduction plate 11, which face is distal from the heat conduction plate 12). In practice, the heat conduction plate assembly 1 is applicable to an isolation case 3 enclosing a heat source 40 as in the first embodiment. In this embodiment, the contact face 121 of the heat conduction plate assembly 1 is in contact with the isolation case 3 (the isolation cover 32). An electroconductive adhesive layer is disposed between the isolation case 3 (isolation cover 32) and the contact face 121 of the heat conduction plate assembly 1, whereby the relevant components are more securely electrically connected with each other (for grounding or other purposes).

The heat spreader 5 is a plate-shaped structure body disposed between the heat conduction plates 11, 12. Electroconductive adhesive layers can be disposed between the heat spreader 5 and the heat conduction plates 11, 12 as necessary. The heat spreader 5 has an elongated main extension section 51 and multiple branch sections 52, 53 obliquely extending from two sides of the main extension section 51 in parallel to each other. The branch sections 52, 53 obliquely extend in a direction away from the heat source 40 and the main extension section 51. The main extension section 51 has a proximal-to-heat-source section 511 proximal to the heat source and a distal-from-heat-source section 512 extending in a direction away from the heat source 40.

In use, most of the heat generated by the heat source 40 is conducted from the isolation case 3 through the contact face 121 to the heat conduction plate 12. The heat spreader 5 then quickly spreads the heat to those sections that are distal from the heat source 40 (to the distal-from-heat-source section 512 of the main extension section 51 and to the free ends of the branch sections 52, 53). Then the heat is conducted back to the heat conduction plates 11, 12 and outward dissipated from the heat conduction plates 11, 12 without accumulating around the isolation case 3.

In conclusion, the heat dissipation structure of electronic shield cover of the present invention can quickly and uniformly dissipate the heat to avoid accumulation of the heat. Moreover, the heat dissipation structure of electronic shield cover of the present invention is manufactured at lower cost.

The above embodiments are only used to illustrate the present invention, not intended to limit the scope thereof. Many modifications of the above embodiments can be made without departing from the spirit of the present invention.

What is claimed is:

1. A heat dissipation structure of electronic shield cover, comprising:
a heat-conductive and magnetically conductive isolation case disposed around at least one preset heat source to enclose the heat source;
at least one heat conduction plate assembly having at least one electroconductive heat conduction plate; and
at least one heat spreader, which is able to quickly conduct heat along the surface, the heat spreader being attached to and in contact with the heat conduction plate assembly, the heat spreader having a proximal-to-heat-source section proximal to the heat source and a distal-from-heat-source section distal from the heat source, at least one of the heat conduction plate assembly and the heat spreader being in contact with the isolation case.

2. The heat dissipation structure of electronic shield cover as claimed in claim 1, wherein the heat conduction plate assembly includes at least two heat conduction plates, the heat spreader being disposed between the heat conduction plates in contact with the heat conduction plates.

3. The heat dissipation structure of electronic shield cover as claimed in claim 2, wherein the heat conduction plates of the heat conduction plate assembly have equal size and identical shape.

4. The heat dissipation structure of electronic shield cover as claimed in claim 1, wherein the heat spreader has an area smaller than that of the heat conduction plates.

5. The heat dissipation structure of electronic shield cover as claimed in claim 2, wherein the heat spreader has an area smaller than that of the heat conduction plates.

6. The heat dissipation structure of electronic shield cover as claimed in claim 3, wherein the heat spreader has an area smaller than that of the heat conduction plates.

7. The heat dissipation structure of electronic shield cover as claimed in claim 1, wherein the heat spreader is an elongated plate body.

8. The heat dissipation structure of electronic shield cover as claimed in claim 2, wherein the heat spreader is an elongated plate body.

9. The heat dissipation structure of electronic shield cover as claimed in claim 4, wherein the heat spreader is an elongated plate body.

10. The heat dissipation structure of electronic shield cover as claimed in claim 1, wherein the heat spreader has an elongated main extension section and at least one branch section obliquely extending from one side of the main extension section.

11. The heat dissipation structure of electronic shield cover as claimed in claim 2, wherein the heat spreader has an elongated main extension section and at least one branch section obliquely extending from one side of the main extension section.

12. The heat dissipation structure of electronic shield cover as claimed in claim 4, wherein the heat spreader has an elongated main extension section and at least one branch section obliquely extending from one side of the main extension section.

13. The heat dissipation structure of electronic shield cover as claimed in claim 5, wherein the heat spreader has an elongated main extension section and at least one branch section obliquely extending from each of two sides of the main extension section.

14. The heat dissipation structure of electronic shield cover as claimed in claim 10, wherein the branch section obliquely extends in a direction away from the heat source assembly and the main extension section.

15. The heat dissipation structure of electronic shield cover as claimed in claim 11, wherein the branch section obliquely extends in a direction away from the heat source assembly and the main extension section.

16. The heat dissipation structure of electronic shield cover as claimed in claim 12, wherein the branch section obliquely extends in a direction away from the heat source assembly and the main extension section.

17. The heat dissipation structure of electronic shield cover as claimed in claim 13, wherein the branch sections obliquely extend in a direction away from the heat source assembly and the main extension section.

18. The heat dissipation structure of electronic shield cover as claimed in claim 1, wherein an electroconductive adhesive layer is disposed between the heat conduction plate assembly and the heat spreader.

19. The heat dissipation structure of electronic shield cover as claimed in claim 2, wherein an electroconductive adhesive layer is disposed between the heat conduction plate assembly and the heat spreader.

20. The heat dissipation structure of electronic shield cover as claimed in claim 3, wherein an electroconductive adhesive layer is disposed between the heat conduction plate assembly and the heat spreader.

21. The heat dissipation structure of electronic shield cover as claimed in claim 4, wherein an electroconductive adhesive layer is disposed between the heat conduction plate assembly and the heat spreader.

22. The heat dissipation structure of electronic shield cover as claimed in claim 7, wherein an electroconductive adhesive layer is disposed between the heat conduction plate assembly and the heat spreader.

23. The heat dissipation structure of electronic shield cover as claimed in claim 10, wherein an electroconductive adhesive layer is disposed between the heat conduction plate assembly and the heat spreader.

24. The heat dissipation structure of electronic shield cover as claimed in claim 14, wherein an electroconductive adhesive layer is disposed between the heat conduction plate assembly and the heat spreader.

25. The heat dissipation structure of electronic shield cover as claimed in claim 1, wherein an electroconductive adhesive layer is disposed between the isolation case and the heat conduction plate assembly.

26. The heat dissipation structure of electronic shield cover as claimed in claim 2, wherein an electroconductive adhesive layer is disposed between the isolation case and the heat conduction plate assembly.

27. The heat dissipation structure of electronic shield cover as claimed in claim 3, wherein an electroconductive adhesive layer is disposed between the isolation case and the heat conduction plate assembly.

28. The heat dissipation structure of electronic shield cover as claimed in claim 4, wherein an electroconductive adhesive layer is disposed between the isolation case and the heat conduction plate assembly.

29. The heat dissipation structure of electronic shield cover as claimed in claim 7, wherein an electroconductive adhesive layer is disposed between the isolation case and the heat conduction plate assembly.

30. The heat dissipation structure of electronic shield cover as claimed in claim 10, wherein an electroconductive adhesive layer is disposed between the isolation case and the heat conduction plate assembly.

31. The heat dissipation structure of electronic shield cover as claimed in claim 14, wherein an electroconductive adhesive layer is disposed between the isolation case and the heat conduction plate assembly.

32. The heat dissipation structure of electronic shield cover as claimed in claim 18, wherein an electroconductive adhesive layer is disposed between the isolation case and the heat conduction plate assembly.

33. The heat dissipation structure of electronic shield cover as claimed in claim 1, wherein the isolation case is composed of an isolation casing surrounding the heat source and an isolation cover mated with upper side of the isolation casing to cover the heat source.

34. The heat dissipation structure of electronic shield cover as claimed in claim 2, wherein the isolation case is composed of an isolation casing surrounding the heat source and an isolation cover mated with upper side of the isolation casing to cover the heat source.

35. The heat dissipation structure of electronic shield cover as claimed in claim 3, wherein the isolation case is composed of an isolation casing surrounding the heat source and an isolation cover mated with upper side of the isolation casing to cover the heat source.

36. The heat dissipation structure of electronic shield cover as claimed in claim 4, wherein the isolation case is composed of an isolation casing surrounding the heat source and an isolation cover mated with upper side of the isolation casing to cover the heat source.

37. The heat dissipation structure of electronic shield cover as claimed in claim 7, wherein the isolation case is composed of an isolation casing surrounding the heat source and an isolation cover mated with upper side of the isolation casing to cover the heat source.

38. The heat dissipation structure of electronic shield cover as claimed in claim 10, wherein the isolation case is composed of an isolation casing surrounding the heat source and an isolation cover mated with upper side of the isolation casing to cover the heat source.

39. The heat dissipation structure of electronic shield cover as claimed in claim 14, wherein the isolation case is composed of an isolation casing surrounding the heat source and an isolation cover mated with upper side of the isolation casing to cover the heat source.

40. The heat dissipation structure of electronic shield cover as claimed in claim 18, wherein the isolation case is composed of an isolation casing surrounding the heat source and an isolation cover mated with upper side of the isolation casing to cover the heat source.

41. The heat dissipation structure of electronic shield cover as claimed in claim 25, wherein the isolation case is composed of an isolation casing surrounding the heat source and an isolation cover mated with upper side of the isolation casing to cover the heat source.
